(19) United States
(12) Patent Application Publication
(10) Pub. No.: US 2019/0352174 A1
(43) Pub. Date: Nov. 21, 2019

(54) POSITION SENSING CIRCUIT FOR AN ELECTRONICALLY DRIVEN MEMS DEVICE

(71) Applicant: Lawrence Livermore National Security, LLC, Livermore, CA (US)

(72) Inventors: Steven L. HUNTER, Livermore, CA (US); Robert M. Panas, Dublin, CA (US)

(21) Appl. No.: 15/983,909

(22) Filed: May 18, 2018

(51) Int. Cl. B81B 3/00; G01D 5/24; G02B 26/08

(52) U.S. Cl. CPC B81B 3/0086; G02B 26/0841; G01D 5/24; B81B 3/0094

(57) ABSTRACT

A system is disclosed for detecting movement of a microelectromechanical system (MEMS) device. The system may include a drive voltage signal source for generating a drive voltage signal for driving the MEMS device. A modulation voltage signal source generates a modulation signal having a frequency above a physical response capability of the MEMS device. A capacitor voltage divider network may be included having a first capacitor, coupled in series with the modulation voltage signal source, and a capacitance of the MEMS device representing a second capacitor which changes in response to movement of the MEMS device. An output component may be coupled in parallel with the second capacitor and produces an output voltage signal. A filter removes the drive voltage signal from the output voltage signal. The output voltage signal is indicative of a position of the MEMS device.

### STATEMENT OF GOVERNMENT RIGHTS

The United States Government has rights in this invention pursuant to Contract No. DE-AC52-07NA27344 between the U.S. Department of Energy and Lawrence Livermore National Security, LLC, for the operation of Lawrence Livermore National Laboratory.

### FIELD

The present disclosure relates to microelectromechanical sensing (MEMS) devices, and more particularly to a system and method for sensing a position of an electrostatically driven MEMS device.

### BACKGROUND

This section provides background information related to the present disclosure which is not necessarily prior art.

Microelectromechanical systems (MEMS) devices are rapidly gaining popularity in a wide variety of applications spanning sensor applications, microactuators, in microelectronics applications, and with microstructures, just to name a few. MEMS devices are now being used in a wide variety of fields including the medical field, automotive applications, and precision measuring and instrumentation fields.

One challenge with MEMS devices is that the physical position of a MEMS device typically has a non-linear dependence on the drive voltage. The MEMS device may in some instances also be acted on by outside forces, which may cause it to move to a position other than its indicated or commanded position.

Other micro-mirror MEMS devices have used open loop control because, up until the present time there, there has been no reliable way to quickly and easily measure the location of the moving portion of the device in real time in closed loop fashion. The disadvantage of open loop control is that since a MEMS device is susceptible to outside forces which can influence its movement/position, the actual position of the MEMS device may differ significantly from its true position. Furthermore, if using an open loop control scheme, each MEMS device may need to be individually characterized to account for manufacturing variations that would need to be taken into account when designing the open loop control scheme/commands.

Accordingly, a system and method for accurately detecting a real time position of a MEMS device, without the aforementioned limitations and drawbacks of an open loop system, would significantly enhance the use and application of a MEMS device.

### SUMMARY

This section provides a general summary of the disclosure, and is not a comprehensive disclosure of its full scope or all of its features.

In one aspect the present disclosure relates to a system for detecting movement of a microelectromechanical system (MEMS) device. The system may comprise a drive voltage signal source for generating a drive voltage signal for driving the MEMS device, and a modulation voltage signal source for generating a modulation signal. The modulation signal may have a frequency selected to be above a physical response capability of the MEMS device such that operation of the MEMS device is not significantly affected by the modulation signal. A capacitor voltage divider network may be included which is formed by a first capacitor coupled in series with the modulation voltage signal source. A capacitance of the MEMS device represents a second capacitor, and the capacitance of the MEMS device changes in response to physical movement of the MEMS device. An output component may be coupled in parallel with the second capacitor and produces an output voltage signal. A filter may be included for removing the drive voltage signal from the output voltage signal. The output voltage signal read across the output component is indicative of a position of the MEMS device.

In another aspect the present disclosure relates to a system for detecting movement of a microelectromechanical system (MEMS) device. The system may include a drive voltage signal source for generating a drive voltage signal for driving the MEMS device. A modulation voltage signal source may be included for generating a modulation signal, with the modulation signal having a frequency selected to be above a physical response capability of the MEMS device such that operation of the MEMS device is not significantly affected by the modulation signal. A capacitor voltage divider network may be included which is formed by a first capacitor coupled in series with the modulation voltage signal source, and a capacitance of the MEMS device representing a second capacitor in parallel with the first capacitor. The capacitance of the MEMS device changes in response to physical movement of the MEMS device. The first capacitor may have a capacitance which is less than about ten times a capacitance of the second capacitor. An output resistor may be coupled in parallel with the second capacitor and produces an output voltage signal. A high pass filter may be included for removing the drive voltage signal from the output voltage signal measured across the output resistor. The output voltage signal produced across the output component is indicative of a position of the MEMS device.

In still another aspect the present disclosure relates to a system comprising a microelectromechanical system (MEMS) device movable between at least first and second positions. The MEMS device may include a system for detecting movement of a (MEMS) device. The system may include a drive voltage signal source for generating a drive voltage signal for driving the MEMS device. A modulation voltage signal source may be included for generating a modulation signal. The modulation signal may have a frequency selected to be above a physical response capability of the MEMS device such that operation of the MEMS device is not significantly affected by the modulation signal. A capacitor voltage divider network is included which is formed by a first capacitor coupled in series with the modulation voltage signal source, and a capacitance of the MEMS device representing a second capacitor coupled in parallel with the first capacitor. The capacitance of the MEMS device changes in response to physical movement of the MEMS device. The first and second capacitors may have capacitances such that the first capacitor is less than ten times a capacitance of the second capacitor. The system may also include an output resistor coupled in parallel with the second capacitor, and producing an output voltage signal. A third capacitor operating in connection with the output resistor may be included to form a high pass filter for removing the drive voltage signal from the output voltage signal measured across the output resistor. The output voltage signal produced across the output component is indicative of a position of the MEMS device.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is a schematic diagram of a system Corresponding reference numerals indicate corresponding parts throughout the several views of the drawings.

### DETAILED DESCRIPTION

Example embodiments will now be described more fully with reference to the accompanying drawings.

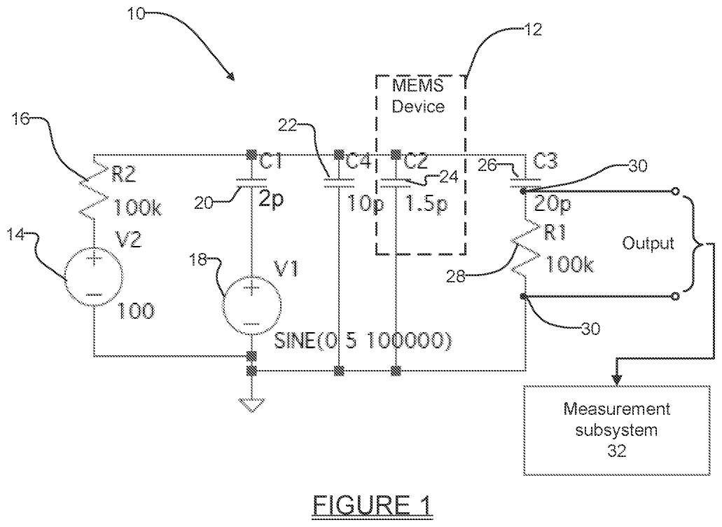

Referring to FIG. 1, a system 10 is shown for detecting a real time positon, angle, orientation, etc., of a MEMS device 12. In this example the MEMS device 12 is a movable device which is movable between at least first and second positions, or between a larger plurality of positions, angles or orientations, in other words over a range of positions, angles or orientations.

The system 10 includes a DC voltage source 14 (V2) which represents the MEMS device 12 drive signal (i.e., DC drive voltage), which in this example is 100 Vdc. As will be appreciated, this is just one example of a suitable drive voltage and the precise drive voltage used will depend in large part of the construction and type of the actual MEMS device 12 being monitored. Resistor 16 (R2) is a current limiting resistor and allows a modulation signal source 18 (V1), which in this example is a 5 Vdc signal @100 KHz, to add to the drive voltage source 14 (V2). This modulation signal may also vary depending on the specific MEMS device being monitored. Resistor 16 (R2) in this example has a value of 100K ohms, but again this value may vary to meet the needs of a specific system design.

Capacitor 20 (C1) is the capacitor that couples the modulation signal from modulation signal source 18 (V1) to the MEMS drive signal. Capacitor 22 (C4) represents parasitic capacitance in the circuit formed by the system 10, which in this example is about 10 p. Capacitor 24 (C2) represents the MEMS device 12 capacitance, which will change in accordance with movement of the MEMS device. Capacitor 26 (C3) is the output coupling capacitor, and the output signal of the system 10 is sampled at the junction of capacitor 26 (C3) and resistor 28 (R1) (i.e., across output points 30). Optionally, the output signal may be transmitted to a measurement subsystem 32 or other form of measurement component (or possibly even to an electronic controller with measurement reading capability) configured to interpret the output signal and to determine the position of the MEMS device 12.

The capacitances of capacitors 20 (C1) and 24 (C2) may vary depending on system requirements and the characteristics of the specific MEMS device 12 being used, but in one example the capacitor 20 (C1) may have a capacitance of 2 p and the capacitance of the MEMS device, represented by capacitor 24 (C2) in FIG. 1, may be about 1.5 p.

The system 10 thus adds a modulation signal from the modulation signal source 18 (V1) to the drive signal voltage generated by the DC voltage drive signal source 14 (V2). The modulation signal frequency (e.g., in this example 100 KHz) is much higher than the physical response capability of the MEMS device 12, so it does not affect the operation of the MEMS device 12. In this example the modulation frequency is 100 KHz, but again this precise frequency may be selected to meet the needs of a specific application and/or a specific MEMS device.

The capacitor 20 (C1) that couples the modulation signal onto the MEMS drive signal (from signal source 14) is similar to the capacitance of the MEMS device 12, which as noted above is represented by the capacitor 24 (C2), so the two capacitors 20/24 form a capacitor voltage divider network. By “similar” it is meant that Capacitor 20 (C1) preferably is less than about 10 times the value of capacitor 24 (C2), although in practice they only need to be similar so that there is a good signal-to-noise ratio between them.

As the MEMS device 12 moves (i.e., changing its position, angle, orientation, etc.), its capacitance changes, and the peak-to-peak voltage of the modulation signal from modulation signal source 18 (V1) also changes as a result. The change in peak-to-peak voltage of the modulation signal source 18 (V1) is due to the change in the ratio of the two capacitors 20 and 24 (C1 and C4).

The signal at the MEMS device 12 is high pass filtered by filtering capacitor 26 (C3) used in combination with an output resistor 28 (R1) to remove the drive signal, if the MEMS device is an active device. Capacitors 20 (C1), 24 (C2) and 26 (C3) are thus coupled in parallel. The change in the modulation signal, which results across the output resistor 28 (i.e., across output points 30), is used to detect the change in the MEMS device 12 position, angle, orientation, etc. The amplitude of the output signal across points 30 can be used by the measurement subsystem 32 to determine the position, angle or orientation (i.e., more broadly movement) of the MEMS device 12, or synchronous rectification may be used to obtain the magnitude and phase of the signal. Synchronous detection provides for much higher noise rejection than filtering alone could provide.

The system 10 thus forms a means for reliably detecting movement and/or a position, angle, orientation, etc. of a MEMS device in real time, and even more importantly, over a range of possible positions, angles or orientations that the MEMS device is capable of. The system 10 can be implemented with relatively low cost and does not affect or influence operation of the MEMS device which it is monitoring.

The system 10 may also be retrofitted to existing circuits or systems being used with a MEMS device, and again, will not influence or otherwise tangibly affect operation of the MEMS device.

While specific voltages, resistances and capacitances have been mentioned in the foregoing discussion, it will be appreciated that these are merely to provide one example of parameters that are suitable in implementing the system 10, but the present disclosure is not limited to use with components have specific voltages, resistances or capacitances.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

What is claimed is:

1. A system for detecting movement of a microelectromechanical system (MEMS) device, comprising:
a drive voltage signal source for generating a drive voltage signal for driving the MEMS device;
a modulation voltage signal source for generating a modulation signal, the modulation signal having a frequency selected to be above a physical response capability of the MEMS device, such that operation of the MEMS device is not significantly affected by the modulation signal;
a capacitor voltage divider network formed by a first capacitor coupled in series with the modulation voltage signal source, and a capacitance of the MEMS device representing a second capacitor, the capacitance of the MEMS device changing in response to physical movement of the MEMS device;
an output component coupled in parallel with the second capacitor, and producing an output voltage signal;
a filter for removing the drive voltage signal from the output voltage signal; and
wherein the output voltage signal read across the output component is indicative of a position of the MEMS device.

2. The system of claim 1, wherein a change in a ratio of voltage drops across the first and second capacitors is used to help form the output voltage.

3. The system of claim 1, wherein the output component is a resistor.

4. The system of claim 1, wherein the filter comprises a high pass filter.

5. The system of claim 4, wherein the high pass filter is formed by a filtering capacitor in series with the output resistor.

6. The system of claim 5, wherein the filtering capacitor operates to block a DC high voltage associated with the drive voltage signal.

7. The system of claim 1, wherein the modulation voltage signal source has a modulation frequency of 100 KHz.

8. The system of claim 1, wherein the first capacitor and the second capacitor forming the capacitor voltage divider network have capacitance values such that the first capacitor has a capacitance value which is less than about 10 times a value of capacitance of the second capacitor.

9. The system of claim 1, further including a current limiting resistor coupled in series with the voltage drive signal source.

10. The system of claim 1, further comprising at least one of an electronic controller and an electronic measurement subsystem configured to receive the output voltage signal from the output component and to interpret the output voltage signal to determine a position of the MEMS device based on the output voltage signal.

11. The system of claim 1, wherein the drive voltage signal source produces a drive voltage of about 100 Vdc, and the modulation voltage signal source produces a voltage of about 5 Vdc with a modulation frequency of about 100 KHz.

12. A system for detecting movement of a microelectromechanical system (MEMS) device, comprising:
a drive voltage signal source for generating a drive voltage signal for driving the MEMS device;
a modulation voltage signal source for generating a modulation signal, the modulation signal having a frequency selected to be above a physical response capability of the MEMS device, such that operation of the MEMS device is not significantly affected by the modulation signal;
a capacitor voltage divider network formed by a first capacitor coupled in series with the modulation voltage signal source, and a capacitance of the MEMS device representing a second capacitor in parallel with the first capacitor, the capacitance of the MEMS device changing in response to physical movement of the MEMS device, the first capacitor having a capacitance which is less than about ten times a capacitance of the second capacitor;
an output resistor coupled in parallel with the second capacitor, and producing an output voltage signal;
a high pass filter for removing the drive voltage signal from the output voltage signal measured across the output resistor; and
wherein the output voltage signal produced across the output component is indicative of a position of the MEMS device.

13. The system of claim 12, wherein the modulation voltage signal source has a modulation frequency of about 100 KHz.

14. The system of claim 13, wherein the high pass filter is formed by a combination of third capacitor placed in series with the output resistor.

15. The system of claim 14, wherein the first, second and third capacitors are coupled in parallel.

16. The system of claim 12, further comprising at least one of an electronic controller and a measurement subsystem for receiving the output voltage signal and using the output voltage signal to interpret a position of the MEMS device.

17. A system comprising:
a microelectromechanical system (MEMS) device movable between at least first and second positions;
a system for detecting movement of a (MEMS) device, the system including:
a drive voltage signal source for generating a drive voltage signal for driving the MEMS device;
a modulation voltage signal source for generating a modulation signal, the modulation signal having a frequency selected to be above a physical response capability of the MEMS device, such that operation of the MEMS device is not significantly affected by the modulation signal;
a capacitor voltage divider network formed by a first capacitor coupled in series with the modulation voltage signal source, and a capacitance of the MEMS device representing a second capacitor coupled in parallel with the first capacitor, the capacitance of the MEMS device changing in response to physical movement of the MEMS device, the first and second capacitors having capacitances such that the first capacitor is less than ten times a capacitance of the second capacitor;
an output resistor coupled in parallel with the second capacitor, and producing an output voltage signal;
a third capacitor operating in connection with the output resistor to form a high pass filter for removing the drive voltage signal from the output voltage signal measured across the output resistor; and
wherein the output voltage signal produced across the output component is indicative of a position of the MEMS device.

18. The system of claim 17, wherein the modulation frequency of the modulation voltage signal source is about 100 KHz.

19. The system of claim 17, further comprising at least one of an electronic controller and a measurement subsystem for reading the output voltage and using the output voltage to determine a position of the MEMS device.
